(19) United States
(12) Patent Application Publication
(10) Pub. No.: US 2026/0221965 A1
(43) Pub. Date: Jul. 30, 2026

(54) TRANSIENT RESPONSE OF A SWITCHING CONVERTER

(71) Applicant: Shaoxing Yuanfang Semiconductor Co., Ltd., Shaoxing (CN)

(72) Inventors: Ramasiddaiah Pamidi, Bangalore (IN); Shyam Somayajula, Bangalore (IN); Ramkishore Ganti, Bangalore (IN)

(21) Appl. No.: 19/324,199

(22) Filed: Sep. 10, 2025

(30) Foreign Application Priority Data
Jan. 28, 2025 (IN) 202541006926
Feb. 4, 2025 (IN) 202541009190

(51) Int. Cl. H03K 17/0812; H02M 1/00; H02M 1/084

(52) U.S. Cl. CPC H03K 17/08122; H02M 1/0009; H02M 1/0038; H02M 1/0845; H03K 2217/0063; H03K 2217/0072

(57) ABSTRACT

A transient handling module (of a switching converter) containing a first circuit portion designed to handle an undershoot of the regulated supply voltage and a second circuit portion designed to handle an overshoot of the regulated supply voltage. Each circuit portion contains a respective capacitor pre-charged to a respective pre-determined voltage and a respective switch coupled between the capacitor and the output node. The capacitor in the first circuit portion is operable to supply current to the output node via the switch upon occurrence of an undershoot. The capacitor in the second circuit portion is operable to draw current from the output node via the switch upon occurrence of an overshoot.

### PRIORITY CLAIM

The instant patent application is related to and claims priority from the co-pending India provisional patent applications: 1) Entitled “Minimizing Undershoot and Overshoot of Output Voltage Due to Fast Load Transients in a Switching Converter”, Serial No.: 202541006926, Filed: 28 Jan. 2025, Attorney docket no.: AURA-371-INPR; and 2) Entitled “Minimizing Undershoot and Overshoot of Output Voltage Due to Fast Load Transients in a Switching Converter”, Serial No.: 202541009190, Filed: 4 Feb. 2025, Attorney docket no.: AURA-371-INPR2, which are incorporated in their entirety herewith to the extent not inconsistent with the description herein.

### BACKGROUND

### Technical Field

Embodiments of the present disclosure relate generally to switching converters, and more specifically to improving transient response of a switching converter.

### Related Art

Switching converters refer to components which convert an input AC (alternating current) or DC (direct current) voltage of one magnitude to an output DC voltage of a desired magnitude by employing and operating switch(es), as is well known in the relevant arts. Switching converters are designed to provide the output voltage of the desired magnitude for a given range of input voltages and load-currents. Switching converters find use as stand-alone power supplies, in voltage regulator modules used in several environments such as laptops, mobile phones, etc.

It is generally desirable that the output voltage be maintained at the desired constant magnitude even when there are changes in operating parameters such as load-current, input voltage, etc. Upon occurrence of such changes, a switching converter takes a finite amount of time to revert the output voltage to the desired constant magnitude.

The switching converter may be said to be in a transient state from the occurrence of the change until the output voltage reaches the desired constant magnitude (within a desired degree of precision). The response of the switching converter in such a transient state may be referred to as transient response, which is generally quantified in terms of the magnitude of variation from the desired constant magnitude and the time taken to return to the desired constant magnitude of the output voltage.

Aspects of the present disclosure are directed to improving transient response of a switching converter.

### BRIEF DESCRIPTION OF THE VIEWS OF DRAWINGS

Example embodiments of the present disclosure will be described with reference to the accompanying drawings briefly described below.

FIG. 1 is a block diagram of an example device in which several aspects of the present disclosure can be implemented.

FIG. 2 is a block diagram illustrating the details of a voltage regulator module (VRM) in an embodiment of the present disclosure.

FIG. 3 is a diagram illustrating the implementation details of a power stage in an embodiment of the present disclosure.

FIG. 4 is a diagram illustrating the implementation details of a transient handling module in an embodiment of the present disclosure.

FIG. 5A is a timing diagram (not to scale) illustrating waveforms at various nodes of a switching converter in an undershoot condition, in an embodiment of the present disclosure.

FIG. 5B is a timing diagram (not to scale) illustrating waveforms at various nodes of a switching converter in an overshoot condition, in an embodiment of the present disclosure.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

An aspect of the present disclosure is directed to a switching converter containing a high-side switch and a low-side switch coupled in series at a switching node. The switches together provide a regulated supply voltage at an output node based on an input voltage received at an input node. The switching converter includes a transient handling module containing a first circuit portion and a second circuit portion, with the first circuit portion designed to handle an undershoot of the regulated supply voltage and the second circuit portion designed to handle an overshoot of the regulated supply voltage.

According to another aspect, the first circuit portion contains a first capacitor having a first terminal and a second terminal, the first terminal being coupled to a constant reference potential. A first switch of the first circuit portion is coupled between the input node and the second terminal of the first capacitor, and a second switch of the first circuit portion is coupled between second terminal of the first capacitor and the output node. In a first time duration, the first switch is closed with the second switch being open such that the first capacitor is charged to a first voltage via the first switch. Upon occurrence of the undershoot of the regulated output voltage following the first time duration, the second switch is closed for a second time duration with the first switch being open in the second time duration such that the output node is coupled to the first capacitor via the second switch to cause the first capacitor to supply current to the output node.

According to another aspect of the present disclosure, the second circuit portion contains a second capacitor having a first terminal and a second terminal, the first terminal being coupled to the constant reference potential. A third switch of the second circuit portion is coupled between the constant reference potential and the second terminal of the second capacitor, and a fourth switch of the second circuit portion is coupled between the second terminal of the second capacitor and the output node. In a third time duration, the third switch is closed with the fourth switch being open such that the second capacitor is discharged to a second voltage via the third switch. Upon occurrence of the overshoot of the regulated output voltage following the third time duration, the fourth switch is closed for a fourth time duration with the third switch being open in the fourth time duration such that the output node is coupled to the second capacitor via the fourth switch to cause the second capacitor to draw current from the output node.

According to one more aspect of the present disclosure, the first voltage is higher than the desired magnitude of the regulated output voltage by a first offset value, wherein the second voltage is lower than the desired magnitude of the regulated output voltage by a second offset value.

In an embodiment, the transient handling module contains a differentiator coupled to receive the regulated output voltage, the differentiator designed to generate a first output signal with a magnitude proportional to a rate of change of the regulated output voltage. An undershoot of the regulated output voltage is determined to have occurred if the rate of change is positive and exceeds a first threshold, and an overshoot of the regulated output voltage is determined to have occurred if the rate of change is negative and a magnitude of the rate of change exceeds a second threshold. The first offset value is based on the first threshold, and the second offset value is based on the second threshold.

Several aspects of the present disclosure are described below with reference to examples for illustration. However, one skilled in the relevant art will recognize that the disclosure can be practiced without one or more of the specific details or with other methods, components, materials and so forth. In other instances, well known structures, materials, or operations are not shown in detail to avoid obscuring the features of the disclosure. Furthermore, the features/aspects described can be practiced in various combinations, though only some of the combinations are described herein for conciseness.

### 2. Example System

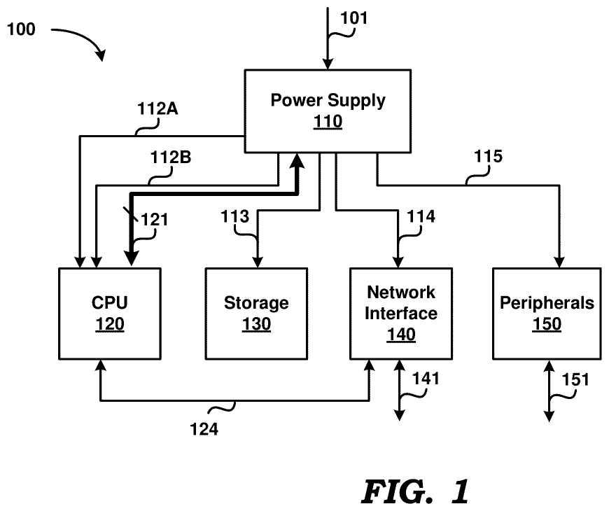

FIG. 1 is a block diagram of an example system in which several aspects of the present disclosure can be implemented. System 100 is shown containing power supply 110, central processing unit (CPU) 120, storage 130, network interface 140 and peripherals 150. In an embodiment, system 100 corresponds to a computer (desktop, laptop, etc.), although system 100 can represent other types of systems in other embodiments. It is understood that system 100 can contain more or fewer blocks than those shown in FIG. 1.

CPU 120, in general, represents a processor or a system-on-chip (SoC), and is shown as receiving a pair of supply voltages (Va and Vb) on respective paths 112A and 112B from power supply 110. As an example, Va may be a lower voltage than Vb, and may be used to power a core portion of CPU which may include arithmetic logic unit (ALU), microprogram sequencer, registers, etc. Vb may be used to power the rest of CPU 120, such as for example, input/output (I/O) units, I/O buffers, on-chip peripherals etc. CPU 120 provides various signals (all deemed to be contained in path 121) specifying, among others, its power supply requirements to power supply 110. Examples of such signals can be those that specify the specific mode of operation (in terms of power consumption) such as PS1, PS2, PS3, etc., which refer to “Power Save States for Improved Efficiency”.

Storage 130 represents a memory that may include both volatile and non-volatile memories. For example, in a personal computer, storage can include magnetic memory (hard disk) as well as solid state memory (RAM, Flash, etc.). Storage 130 is shown receiving a supply voltage on path 113 for powering various circuits and blocks within.

Network interface 140 operates to provide two-way communication between system 100 and a computer network, or in general the Internet. Network interface 140 implements the electronic circuitry required to communicate using a specific physical layer and data link layer standard such as Ethernet or Wi-Fi™. Network interface 140 may also contain a network protocol stack to allow communication with other computers on a same local area network (LAN) and large-scale network communications through routable protocols, such as Internet Protocol (IP). Network interface 140 receives a power supply on path 114 for powering internal circuits and blocks. Network interface 140 receives from/transmits to external systems and CPU 120 respectively on path 141 and path 124.

Peripherals 150 represents one or more peripheral circuits, such as, for example, speakers, microphones, user interface devices, etc. Peripherals 150 receives a power supply on path 115, and communicates with external devices on path 151.

Power supply 110 receives power from one or more sources (e.g., battery) on path 101, and operates to provide the desired power supply voltages on paths 112A, 112B, 113, 114 and 115. In an embodiment, power supply 110 is designed to contain one or more multi-phase DC-DC converters within to generate the power supply voltages. Power supply 110 responds to signals from CPU 120 received on path 121 to control the multi-phase converters to reduce/increase current output based on the specific signal (e.g., PS1, PS2 and PS3).

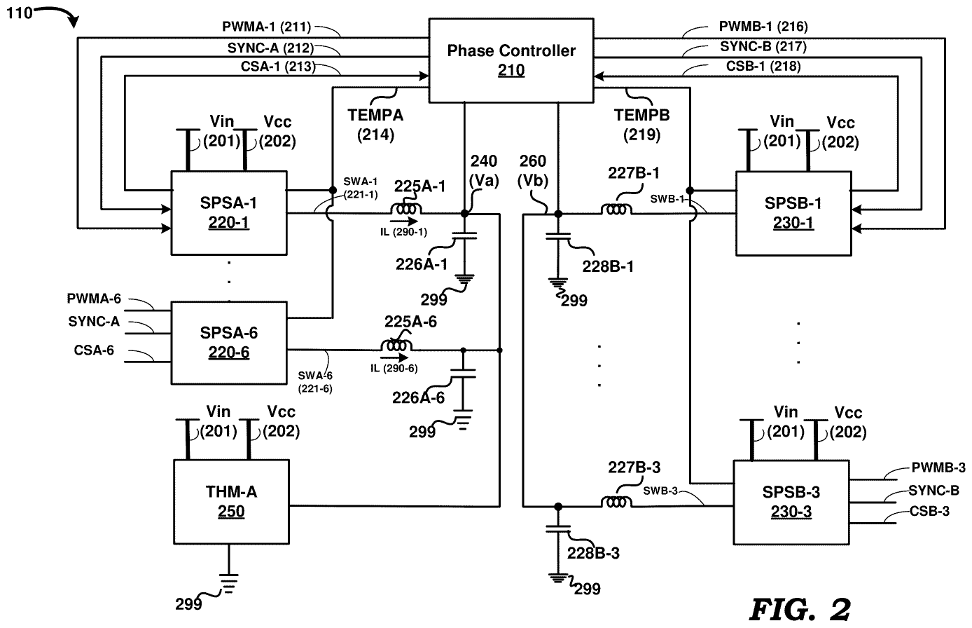

In the embodiment, power supply 110 is a voltage regulator module (VRM), sometimes also called processor power module (PPM), and contains one or more step-down switching (buck) converters to generate several lower voltages from a higher-voltage supply source. In other embodiments however, other types of DC-DC converters such as boost, buck-boost, hysteretic converters etc., can be implemented instead of a buck converter. With a VRM, multiple devices/ICs requiring different supply voltages can be mounted on the same platform, for example, a computer motherboard of a personal computer (PC). Accordingly, the description is continued with respect to a VRM as shown in FIG. 2.

### 3. Voltage Regulator Module (VRM)

FIG. 2 is a block diagram illustrating the details of a VRM in an embodiment of the present disclosure. Power Supply 110 (of FIG. 1) is implemented as a Voltage Regulator Module implemented in the form of a multi-phase switching converter generating two regulated voltages Va (240) and Vb (260).

VRM 110 is shown containing phase controller 210, smart power stages (SPS/power stages) SPSA-1 (220-1) through SPSA-6 (220-6), SPSB-1 (230-1) through SPSB-3 (230-3), inductors 225A-1 through 225A-6 and 227B-1 through 227B-3, output capacitors 226A-1 through 226A-6 and 228B-1 through 228B-3, and transient handling module THM-A 250. Node 299 represents ground terminal (0 Volts). It is noted here that, in general, the term ‘voltage regulator’ refers to either a stand-alone regulator (such as a stand-alone switching converter) or a portion (such as a smart power stage) of a stand-alone regulator.

Power supply Va (240) (Rail-A) is generated by a 6-phase buck converter (there are six SPSs-220-1 through 220-6), while power supply Vb (260) (Rail-B) is generated by a 3-phase buck converter (there are three SPSs-230-1 through 230-3). Nodes/Paths 240 and 260 can correspond to paths 112A and 112B of FIG. 1. Also shown in FIG. 2 are the switching nodes 221-1 to 221-6 of the corresponding power stages. In the interest of conciseness, other power supply circuits that generate supplies on paths 113, 114 and 115 are not shown in FIG. 2. The smart power stages will individually or collectively be referred by reference number 220/230, as will be clear from the context. Also, inductors 225A-1 through 225A-3 and 227B-1 through 227B-4 may be collectively or individually referred to by respective numerals 225 and 227, as will also be clear from the context. Similar convention is followed for other blocks/components/signals throughout the disclosure. It is noted herein that although not shown in FIG. 2 in the interest of conciseness, Rail-B would have a corresponding transient handling module connected in parallel with SPSB.

In an embodiment of the present disclosure, each of the power stages as well as the phase controller is implemented as separate integrated circuits (ICs), and transient handling module 250 is implemented as a discrete component (e.g., on a printed circuit board). In the embodiment, the form factor of transient handling module 250 is identical to that of SPS 220. However, in other embodiments, the implementations of the power stages, phase controller and transient handling module may be different.

Phase controller 210 in conjunction with one or more power stages of a rail operates to generate a regulated voltage as output. In the example of FIG. 2, phase controller 210 and one or more of the power stages of Rail-A, namely SPSA-1 through SPSA-6, operate to generate regulated voltage Va (240) of a desired constant magnitude (Va-ref). Similarly, phase controller 210 and one or more of the power stages of Rail-B, namely SPSB-1 through SPSB-3, operate to generate regulated voltage Vb (260) of a desired constant magnitude (Vb-ref).

The combination of (corresponding circuitry within) phase controller 210, an SPS and the corresponding inductor and capacitor forms one “phase” of a rail. Thus, for example, SPSA-1, inductor 225A-1, capacitor 226A-1, and the corresponding portion within phase controller 210 form a single buck converter, and one phase of the 6-phase buck converter. It is noted here that, while each phase is shown as having its own separate capacitor (e.g., 226A-1), in another embodiment, only a single larger capacitor (larger capacitance) may be employed at node 240 (as well as 260). In other embodiments, multiple capacitors are placed close to the load powered by the corresponding supply voltage.

It may be appreciated that the combination of phase controller 210 and one set of SPSes along with the external inductor, capacitor, etc., operates as a switching converter to provide a regulated output voltage. The term ‘switching converter’ as used herein includes a stand-alone switching converter (i.e., a non-multi-phase converter), a switching converter of a multi-phase voltage regulator or multi-phase regulator module having several independent switching converters, and also a portion of a switching converter, such as for example a smart power stage (SPS).

Phase controller 210 may be designed to implement automatic phase management (APM). Accordingly, the specific number of power stages (or phases) operated by phase controller 210 can vary depending, for example, on the magnitude of load-current drawn from a rail (e.g., Va 240). In general, the smaller the load-current is, fewer are the number of power stages used/operated and vice-versa.

As an example, for very low load-currents drawn from rail-A (Va 240) phase controller 210 may use/operate only one power stage (termed the ‘active’ power stage) to generate Va, and maintain the other five power stages in an ‘inactive’ state. Therefore, phase controller 210 generates the PWM signal to control switching of the high-side and low-side switches of only the one active power stage to generate Va, and maintain the PWM signals to the other five power stages in the Hi-Z state. Therefore, the high-side and low-side switches of those five inactive power stages would all be OFF (not switching).

Each SPS (or in general a ‘power stage’) may be implemented to contain a high-side switch, a low-side switch, gate drive circuitry for the two switches, a temperature monitor circuit and an inductor-current sense circuit/block to provide information indicating the magnitude of inductor-current (290) to phase controller 210. The current supplied by an SPS, and therefore the corresponding inductor-current generally depends on the load-current drawn from the supply voltage, although the high-side switch and low-side switch of an SPS may be viewed as ‘driving’ the inductor. Under steady-state, the average inductor-current equals the load-current in order to maintain the regulated output voltage at the desired magnitude. Each SPS receives a source of power (which can all be the same source) as an input which is connected to the high-side switch (shown in detail in sections below). In FIG. 2, the supply source is numbered 201, and has a voltage Vin. An example value of Vin in an embodiment of VRM 110 is about 12 volts (V). SPS 220 is also shown receiving voltage Vcc at power terminal 202.

Each SPS communicates with phase controller 210 via corresponding signals PWM, SYNC, CS and TEMP. Thus, SPSA-1 is shown connected to phase controller 210 through signal/paths PWMA-1 (211), SYNC-A (212), CSA-1 (213) and TEMPA (214). SPSA-6 communicates with phase controller 210 via signals PWMA-6, SYNC-A, CSA-6 and TEMPA (214), although in FIG. 2, the respective connections of signals PWMA-6, SYNC-A and CSA-6 to phase controller 210 are not shown. Similarly, SPSB-1 is shown connected to phase controller 210 through signal/paths PWMB-1 (216), SYNC-B (217), CSB-1 (218) and TEMPB (219). SPSB-3 communicates with phase controller 210 via signals PWMB-3, SYNC-B, CSB-3 and TEMPB (219), although in FIG. 2, the respective connections of signals PWMB-3, SYNC-A and CSB-3 to phase controller 210 are not shown. The other SPSs would have similar connections with phase controller 210.

Signal TEMP is an output (e.g., a voltage) from an SPS to phase controller 210, and provides information regarding the temperature in the SPS. Phase controller 210 may process the TEMP signal (or the information contained in it) to adjust the current supplied by that phase, or for shut-down of the VRM in the event of a fault indicating over-temperature condition. The TEMP outputs of each phase of a converter are wired together, and a single input (for e.g., TEMPA 214) is connected to phase controller 210. The maximum of the TEMP outputs of a phase is driven on the wired connection.

Signal SYNC is an input to an SPS and may be used by phase controller 210 for the purposes of waking-up the SPS upon power-up of the power supply 110, and also to indicate the power-mode (e.g., PS2, PS3), i.e., output current requirement, of the multi-phase converter. Typically, all SPSs of the same converter share a single SYNC signal (e.g., SYNC-A 212). Signal SYNC is set to the Hi-Z state to signal that the SPSes are to be shut down, i.e., all SPSes are to become inactive, and the corresponding power supply is not generated. In an embodiment, the Hi-Z state is a voltage level/band between the logic HIGH and logic LOW voltage levels of the SYNC signal. A ‘SYNC=Hi-Z’ condition is treated as a “chip disable” signal by internal state machines (not shown) in a power stage, and the state machines shut down all the other internal blocks in the power stage. A ‘SYNC=HIGH’ may be used for chip enable or chip reset.

Signal CS (current-sense) is an input to phase controller 210 from an SPS/phase, and contains information regarding the instantaneous magnitude of the inductor-current of that phase. The information can be in the form of a current, voltage, digital values, etc., depending on the specific implementation of the power stages and phase controller 210. A CS block in an SPS implements the current-sense operation and sends signal CS to phase controller 210.

In an embodiment of the present disclosure, the current-sense block of a power stage sends the sensed inductor-current information to phase controller 210 in the form of a current that can be of either the same magnitude as the inductor-current or (more typically) be a scaled-down version (in terms of magnitude) of the inductor-current. Correspondingly, in the embodiment, phase controller 210 is designed to receive the information in the form of a current, with the scaling factor being known to phase controller 210 as well as the (corresponding) power stage when scaling is used.

Signal PWM is an input to an SPS from phase controller 210, and may be viewed as a ‘phase control signal’ that controls the operation (ON and OFF states) of the power switches in the SPS of the corresponding phase. A cycle/period of signal PWM consists of a first interval (ON-time) in which only the high-side (HS) switch of SPS is switched ON, and a second interval in which only the low-side (LS) switch of the SPS is switched ON. The PWM signal (or more typically, drive signals derived from the PWM signal) controls the opening and closing of high-side switch and low-side switch of the SPS.

In an embodiment of the present disclosure, phase controller 210 employs a constant-ON-time control technique to generate Va. Accordingly, in such an embodiment, signal PWM is a variable frequency, fixed pulse-width (constant-ON-time) signal (i.e., pulse-frequency modulated signal), although the acronym PWM is still used herein to refer to such a signal for ease of reference). The frequency of the signal is generally proportional to the desired regulated voltage (Va) and the load-current.

In an alternative embodiment, phase controller 210 may dynamically adjust the ON-time based on magnitudes of input voltage (Vin), Va and load-current such that the switching frequency is kept fairly constant over input voltage range. Such a control technique is referred to as adaptive on-time control, as is well known in the relevant arts. However, in general, signal PWM may have other characteristics depending on the specific implementation details of power supply 110.

In yet another embodiment, signal PWM can change between a constant-ON-time variable-frequency signal and a fixed-frequency pulse-width modulated signal, based on load-current requirements, desired efficiency of power supply 110 and other considerations, as would be apparent to one skilled in the relevant arts.

As is well known in the relevant arts, the PWM signals to each SPS of a same multi-phase voltage regulator are staggered/interleaved, i.e., delayed with respect to each other in phase such that typically no two high-side switches in the converter (i.e., respective SPSs) will be turned-ON at the same time instant. Such a technique is employed for reasons such as, for example, to ensure that the peak instantaneous current drawn from Vin is relatively low at all times, efficiency, reduced ripple in the output voltage, etc.

When logic LOW is detected by the SPS on signal PWM, the low-side switch is turned ON, and when logic HIGH is detected on signal PWM, the high-side switch is turned ON. Upon detecting a high-impedance (hi-Z) state (typically mid-rail voltage between power supply and ground) on signal PWM the SPS turns OFF both its high-side and the low-side switches. Thus, an SPS is said to be ‘active’ when the corresponding PWM signal is toggling between the HIGH and LOW states thereby contributing to generation of the output voltage and current, and is said to be ‘inactive’ when the corresponding PWM signal is in hi-Z state (mid-rail voltage between logic HIGH and logic-LOW voltages). In the inactive state, the power stage does not contribute to load-current.

Phase controller 210 controls the operation of the power stages via the signals noted above to provide various functions including regulating functions to enable the generation of regulated voltages Va and Vb by the corresponding sets of power stages. Accordingly, Va and Vb are shown as being provided as inputs to phase controller 210 to enable operation of one or more feedback loops within phase controller 210 to regulate Va and Vb. Phase controller 210 also receives inductor-current information (current flowing through each of the inductors) from each of the SPSs to enable various operations such as current-mode control of voltage regulation, current limiting, short circuit protection, and balancing the currents generated by each SPS of a same rail (e.g., rail Va) so as to make the currents from each SPS substantially equal in magnitude. Phase controller 210 may additionally perform various other operations which are not noted here in the interest of conciseness.

The description is continued to illustrate an example implementation of a power stage according to aspects of the present disclosure.

### 4. Smart Power Stage (SPS)

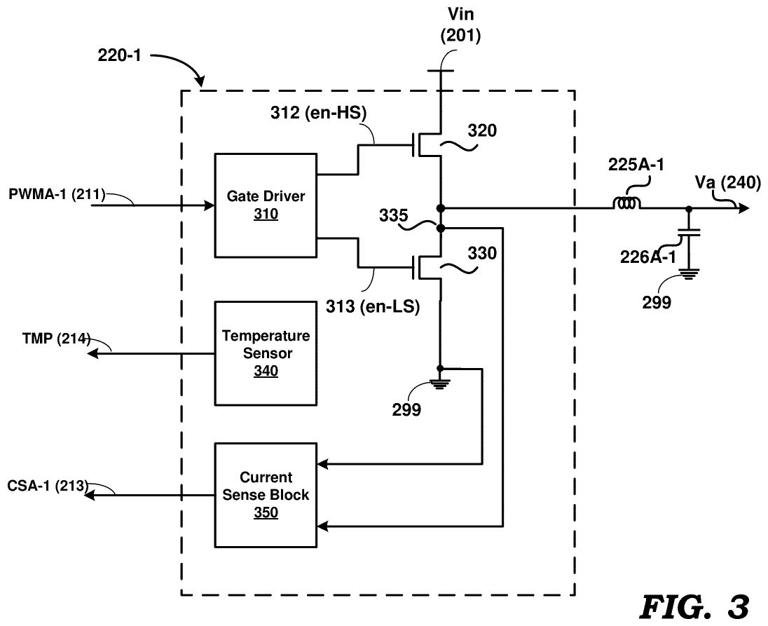

FIG. 3 is a block diagram illustrating the implementation details of a power stage in an embodiment of the present disclosure. SPSA-1 (220-1) is shown in detail in FIG. 3. The other SPSs can also be implemented to be similar to SPSA-1. SPSA-1 is shown containing gate driver 310, high-side (HS) switch 320, low-side (LS) switch 330, temperature sensor 340 and current sense block 350. Also shown in FIG. 3 are inductor 225A-1, output capacitor 226A-1. The drain terminal of HS switch 320 is connected to Vin (201), and the source terminal of LS switch 330 is connected to ground (299). Although not shown in FIG. 3 in the interest of conciseness, power stage 220 may contain various other blocks/circuits such as level-converters for gate driver 310, zero-current detector, etc. Node 240 provides the supply voltage Va.

Gate driver 310 receives signal PWMA-1, and in response to the logic level of PWMA-1 generates the appropriate voltage to turn ON and turn OFF HS switch 320 and LS switch 330 in corresponding intervals indicated by PWMA-1. HS switch 320 and LS switch 330 are each shown implemented as a MOSFET (Metal Oxide Semiconductor Field Effect Transistor) with gate driver 310 driving the gate terminals of the MOSFETs, although alternative embodiments may implement the switches differently. In the example of FIG. 3, when PWMA-1 is a logic high, gate driver 310 generates respective appropriate voltages on paths 312 (en-HS) and 313 (en-LS) to switch ON MOSFET 320 and switch OFF MOSFET 330. When PWMA-1 is a logic low, gate driver 310 generates respective appropriate voltages on paths 312 and 313 to switch OFF MOSFET 320 and switch ON MOSFET 330. When PWMA-1 is in a Hi-Z (High-impedance or mid-rail) state, gate driver 310 generates the respective appropriate voltages on paths 312 and 313-1 to 313-4 to switch-OFF both of MOSFET 320 and 330. Gate driver 310 can be implemented in a known way.

It is noted here that rather than a single block, two separate gate drivers may instead be employed—one for driving the gate of the HS switch to be ON or OFF, and another for driving the gate of the LS switch to be ON or OFF.

Temperature sensor 340 measures the ambient temperature at SPS 220-1 periodically, and provides the temperature values on path 214. Temperature sensor 340 can be implemented in a known way.

Current-sense block 350 operates to determine the magnitude (for example, instantaneous magnitude) of the inductor-current through inductor 225A-1, and provides information indicating the inductor-current magnitude on path 213. Current-sense block 350 may determine the magnitude of the inductor-current by one of several known ways. For example, in FIG. 3 current-sense block 350 is shown as receiving respective voltage-drops across switches 320 and 330. Current-sense block 350 obtains the instantaneous magnitude of the inductor-current (or a scaled-down version thereof) based on the voltage-drops. Current-sense block 350 can be implemented in a known way.

As is well known in the relevant arts, changes in the load-current (load transients) can cause Va (240) to increase (overshoot) or decrease (undershoot) with respect to the corresponding desired constant magnitude. For example, when the load-current drawn by Rail-A increases from its current value, Va falls below Va-ref. The feedback loop inside phase controller 210 senses the fall, and operates to bring Va back to Va-ref. As an example, phase controller 210 may increase ON-time and/or activate one or more phases in order to meet the increased load-current. A decrease in load-current from its current value would cause Va to rise above Va-ref. The feedback loop inside phase controller 210 senses the rise, and operates to bring Va back to Va-ref. Greater the increase or decrease in load-current from its current value, greater would be the fall and rise in Va (240) respectively.

Several factors affect the speed with which the feedback loop corrects any change in Va. Some of these factors include the inductance value of inductors 225, the capacitance value of capacitors 226, the rate of change of load-current, the magnitude of rise/fall in Va, etc. For example, when VRM 110 is implemented as a multi-phase switching converter as in the example of FIG. 2, upon occurrence of an undershoot, the ON-time of PWM signal may be increased to build more inductor-current in each of the active power stages in order to bring the magnitude of Va back to Va-ref. The speed of such correction may be limited by the inductor-current slew-rate, which is inversely proportional to the inductance value (of inductor 225). However, reducing the inductance value (with everything else remaining the same) may result in lower efficiency due to higher inductor-current ripple.

Other prior approaches such as using large output capacitors (226) or increasing the number of power stages (220) may result in corresponding drawbacks such as increased area or increased bill of materials (BOM). Yet another prior approach employs trans-inductor voltage regulator (TLVR) topology for improving the transient response. However, increased ripple in the output voltage and reduced efficiency of the converter may make the approach unacceptable at least in certain environments.

A switching converter implemented according to several aspects of the present disclosure improves the transient response without one or more of drawbacks noted above, as described in detail below with respect to example embodiments.

The description is continued to illustrate an example implementation of a transient handling module according to aspects of the present disclosure.

### 5. Transient Handling Module

According to an aspect of the present disclosure, a switching converter includes a transient handling module (THM-A, 250) placed in parallel to the SPSs, which operates to improve the transient response of the switching converter. The transient handling module is designed to quickly supply current to (or draw current from) node Va in response to undershoot (or overshoot) conditions caused by load transients.

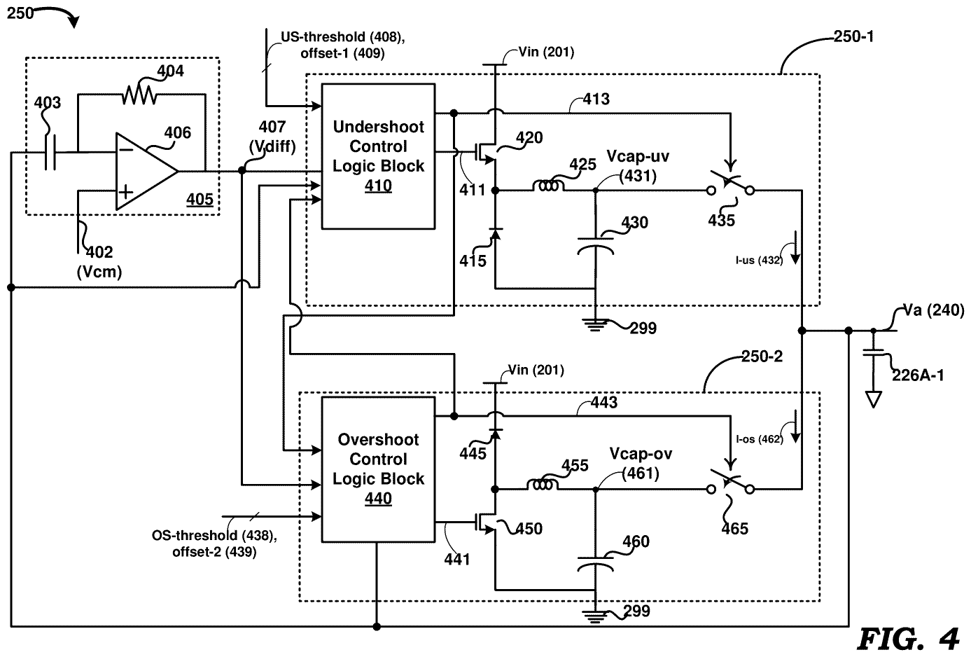

FIG. 4 is a diagram illustrating the implementation details of a transient handling module in an embodiment of the present disclosure. THM-A 250 is shown containing differentiator 405, and circuit portions 250-1 and 250-2. Circuit portion 250-1 in turn is shown containing undershoot control logic block 410, switches 420 and 435, inductor 425, diode 415 and capacitor 430. Circuit portion 250-2 is shown containing overshoot control logic block 440, switches 450 and 465, inductor 455, diode 445 and capacitor 460. Also shown in FIG. 4 is output capacitor 226A-1. Components of transient handling module 250 are powered by Vcc (not shown).

Differentiator 405 in turn is shown containing capacitor 403, resistor 404, and op-amp 406. Common-mode voltage 402 (Vcm) is an internally generated voltage that is used to maintain Vdiff 407 at a level midway between the power supply and ground terminals of comparators (not shown) inside blocks 410 and 440, which may respectively be Vcc and 299. In an embodiment, switches 420, 435, 450 and 465 are implemented as MOSFETs.

Differentiator 405 generates voltage 407 (Vdiff) with a magnitude that is proportional to the rate of change of Va with respect to time, with the magnitude being dependent on the values of capacitor 403 and resistor 404. Since a change in load-current results in corresponding change (increase/decrease) in Va, Vdiff is also proportional to the magnitude of change in load-current. In other words, since current across capacitor (226A-1) is governed by the equation I=C*(dVa/dt), measuring (dVa/dt) indirectly measures load-step magnitude. Higher the magnitude of the step-change, higher would be Vdiff and vice versa. Output voltage Vdiff is connected to blocks 410 and 440.

Circuit portion 250-1 operates to supply current to node 240 upon occurrence of an undershoot caused by a positive load-step greater than a certain threshold as determined by magnitude of Vdiff exceeding US-threshold (408). Circuit portion 250-1 also pre-charges capacitor 430 such that voltage across capacitor 430 is at a magnitude higher than voltage Va-ref by an offset (offset-1, 409), keeping block 250 ready to handle a future undershoot event.

Circuit portion 250-2 operates to draw current from node 240 upon occurrence of an overshoot caused by a negative load-step greater than a certain threshold as determined by magnitude of Vdiff exceeding OS-threshold (438). Circuit portion 250-2 also discharges capacitor 460 such that voltage across capacitor 460 is at a magnitude lower than voltage Va-ref by an offset (offset-2, 439), keeping block 250 ready to handle a future overshoot event.

It may be appreciated that transient handling module 250 operates to handle large load transients (Vdiff exceeding the corresponding undershoot and overshoot thresholds noted above), which likely may not be fully corrected quickly/efficiently by the feedback loop inside phase controller 210.

Undershoot control logic block 410 receives magnitudes of offset-1 (409), US-threshold (408), Vdiff (407), Va (240), signal 443 from block 440, and generates a gate drive signal on path 411 to turn ON and turn OFF switch 420, and a control signal on path 413 to turn ON and turn OFF switch 435. Block 410 operates to pre-charge capacitor 430 to a voltage of magnitude (Va-ref plus offset-1) by turning ON switch 420.

Upon occurrence of an undershoot of Va due to an increase in load-current, block 410 turns ON switch 435 only if all of the following conditions are met:
1. Vdiff exceeds a pre-determined threshold (US-threshold, 408);
2. Voltage across capacitor 430 exceeds Va-ref by a first threshold (dV1); and
3. Switch 465 is in OFF condition. The condition ensures that switches 435 and 465 are not ON simultaneously.

As noted above, magnitude of ‘US-threshold’ represents a corresponding step-change (increase) of load-current from a present value for which transient handling module (specifically circuit portion 250-1) is designed to supply current to node 240. In an embodiment, circuit portion 250-1 is designed to supply current to node 240 only for load transients caused by load-steps exceeding 350 Amperes (A).

The ‘first threshold’ (dV1) represents the minimum voltage by which voltage across capacitor 430 must exceed Va-ref for logic block 410 to turn ON switch 435 upon occurrence of an undershoot. In an embodiment, the first threshold equals 350 mV (for ‘offset-1’ magnitude of 400 mV). Thus, if a first undershoot occurs resulting in discharging of capacitor 430, and a second undershoot occurs even before capacitor 430 is charged to at least dV1, block 410 does not turn ON switch 435.

When switch 435 is turned ON (with switch 420 being in OFF condition), capacitor 430 discharges via switch 435 to supply current to node 240 (i.e., charge is transferred from capacitor 430 to output capacitor 226). Switch 435 is kept ON for a pre-determined duration (undershoot-on-time), or until turn-ON of switch 465 (as indicated by signal received on path 443 from block 440), whichever is earlier.

Magnitude (Va plus offset-1) represents the voltage that capacitor 430 needs to be at in order to quickly supply a pre-determined quantum of charge to node 240 upon occurrence of an undershoot with Vdiff exceeding US-threshold. The charge on capacitor 430 is transferred to output capacitor 226 until the voltage on the two capacitors equalizes. Magnitudes of ‘US-threshold’, ‘offset-1’ and ‘undershoot-on-time’ are determined a priori (at design) based on factors such as the expected load-step magnitudes and load-current slew-rate for the application using VRM 110, loop bandwidth of the control loop inside phase controller 210, magnitude of Va-ref, capacitance value of 226, the operating frequency range of VRM 110, etc. In an embodiment, offset-1 equals 400 mV, and ‘undershoot-on-time’ equals the maximum ON-time duration of signal PWM. Logic block 410 ensures that switches 435 and 465 are not turned ON simultaneously.

It may be appreciated that by pre-charging capacitor 430 to a voltage higher than Va-ref by a pre-determined offset value (offset-1), capacitor 430 is designed to supply just the ‘right’ amount of charge to the output node so as to minimize the undershoot without negatively impacting the efficiency of VRM 110. There is no need for an explicit current-limiting resistor in the path from capacitor 430 to node 240 because ON-resistance of switch 435 itself will be sufficient to limit the current supplied by capacitor 430. Therefore, power losses may be minimized. Further, very precise control of ON time of switch 435 may not be required since charge transfer from capacitor 430 to node 240 will eventually stop once voltages Vcap-uv and Va are equal, thus reducing the design complexity.

Further, by supplying the ‘right’ amount of charge only for a brief interval upon occurrence of an undershoot, the operation/response of the feedback loop inside phase controller 210 is not significantly impacted, thereby allowing build-up of current in the power stages in response to the undershoot.

Subsequent to turning OFF switch 435, block 410 turns ON switch 420 to pre-charge capacitor 430, thus keeping it ready to handle a next undershoot event. For the very first time upon power-up of VRM 110 (and prior to the occurrence of a first undershoot subsequent to the power-up), block 410 pre-charges capacitor 430 upon receipt of a chip enable/reset signal (e.g., a logic HIGH on SYNC signal noted above) from phase controller 210.

Block 410 monitors voltage (Vcap-uv) across capacitor 430 and turns OFF switch 420 when the voltage reaches the magnitude of (Va-ref plus offset-1). Inductance value (L1) of inductor 425 limits the current slew-rate of charging capacitor 430. In an embodiment, inductance value of inductor 425 is 20% of that of inductor 225A (of SPS 220), and capacitance value (C1) of capacitor 430 is 10% of that of output capacitor 226A. In general, the inductance value of inductor 425 and capacitance value of capacitor 430 may be selected such that an optimum trade-off may be achieved between charging time of capacitor 430 and efficiency of the switching converter, as will be apparent to a skilled practitioner by reading the disclosure herein. Also, for the pre-determined quantum of charge to be supplied by capacitor 430 upon occurrence of an undershoot, higher the capacitance value of capacitor 430, lower is the magnitude of ‘offset-1’ (and vice versa). Thus, if a larger capacitance value (limited by the area constraints of the board) is selected, ‘offset-1’ is of a lower magnitude.

Diode 415 operates as a free-wheeling diode. Specifically, when switch 420 is turned OFF upon Vcap-uv reaching (Va-ref plus offset-1), diode 415 provides a path for the energy stored in inductor 425 to dissipate safely, preventing voltage spikes and potential damage to switch 420.

In an embodiment, hysteresis control loop (not shown in the Figure) is implemented inside block 410 with a reference voltage of magnitude (Va-ref plus offset-1), feedback voltage of Vcap-uv (431) and a hysteresis band/window bounded by corresponding upper and lower thresholds to turn-ON and turn-OFF switch 420. For example, assuming Va equals 1V, ‘offset-1’ equals 400 milli-Volts (mV), and lower threshold equals 50 mV, hysteresis control loop inside block 410 ensures that switch 420 is turned ON when Vcap-uv falls below 1.35 V, and is turned OFF when Vcap-uv reaches 1.4 V. Undershoot control logic block 410 can be implemented in a known way.

Overshoot control logic block 440 receives magnitudes of offset-2 (439), OS-threshold (438), Vdiff (407), Va (240), and signal 413 from block 410, and generates a gate drive signal on path 441 to turn ON and turn OFF switch 450, and a control signal on path 443 to turn ON and turn OFF switch 465. Block 440 operates to pre-charge capacitor 460 to a voltage of magnitude (Va-ref minus offset-2) by turning ON switch 450.

Upon occurrence of an overshoot of Va due to a decrease in load-current, block 440 turns ON switch 465 only if all of the following conditions are met:
1. Vdiff exceeds a reference magnitude (OS-threshold, 438); and
2. Switch 435 is in OFF condition. The condition ensures that switches 435 and 465 are not ON simultaneously.

As noted above, magnitude of ‘OS-threshold’ represents a corresponding step-change (decrease) of load-current from a present value for which transient handling module (specifically circuit portion 250-2) is designed to draw current from node 240. In the illustrative embodiment, circuit portion 250-2 is designed to draw current from node 240 only when load-step exceeds 350A.

When switch 465 is turned ON (with switch 445 being in OFF condition), capacitor 460 charges via switch 465 to draw current from node 240 (i.e., charge is transferred from output capacitor 226 to capacitor 460). Switch 465 is kept ON for a pre-determined duration (overshoot-on-time), or until turn-ON of switch 435 (as indicated by signal received on path 413 from block 410), whichever is earlier.

Magnitude (Va-ref minus offset-2) represents the voltage that capacitor 460 needs to be at in order to quickly draw a pre-determined quantum of charge upon occurrence of an overshoot with Vdiff exceeding OS-threshold. Magnitudes of OS-threshold, ‘offset-2’ and ‘overshoot-on-time’ are determined a priori (at design) based on factors such as the expected load-step magnitudes, loop bandwidth of the control loop inside phase controller 210, magnitude of Va-ref, capacitance value of 226, the operating frequency range and load-current slew-rate of VRM 110, etc. In an embodiment, offset-2 equals 400 mV, and overshoot-on-time equals the maximum ON-time duration of signal PWM. Logic block 440 ensures that switches 435 and 465 are not turned ON simultaneously.

It may be appreciated that by pre-charging capacitor 460 to a voltage lower than Va-ref by a pre-determined offset value, capacitor 460 is designed to sink just the ‘right’ amount of charge from the output node so as to minimize the overshoot without negatively impacting the efficiency of VRM 110. As noted above with respect to circuit portion 250-1, there is no need for an explicit current-limiting resistor in the path from node 240 to capacitor 460, thus minimizing power losses.

Subsequent to turning OFF switch 465, block 440 turns ON switch 450 to discharge capacitor 460, thus keeping it ready to handle a next overshoot event. Block 440 monitors voltage (Vcap-ov) across capacitor 460 and turns OFF switch 450 when the voltage reaches the magnitude of (Va-ref minus offset-1). For the very first time upon power-up of VRM 110 (and prior to the occurrence of a first overshoot subsequent to the power-up), Vcap-uv (461) is at 0V.

Inductor 455 limits the current slew-rate of discharge of capacitor 460. In an embodiment, inductance value of inductor 455 is 20% of that of inductor 225A (of SPS 220), and capacitance value of capacitor 460 is 10% of that of output capacitor 226A. In general, the inductance value of inductor 455 and capacitance value of capacitor 460 are selected such that capacitor 460 is discharged quickly to the desired voltage (Va-ref minus offset-2) without substantially negatively impacting efficiency. As noted above with respect to circuit portion 250-1, for the pre-determined quantum of charge to be drawn by capacitor 460 upon occurrence of an overshoot, higher the capacitance value of capacitor 460, lower is the magnitude ‘offset-2’ (and vice versa).

Diode 445 operates as a free-wheeling diode, and provides a path for the energy stored in inductor 455 to dissipate safely, preventing voltage spikes and potential damage to switch 450.

In an embodiment, hysteresis control loop (not shown in the Figure) is implemented inside block 440 with a reference voltage of magnitude (Va-ref minus offset-2), feedback voltage of Vcap-ov (461) and a hysteresis band/window bounded by corresponding upper and lower thresholds to turn-ON and turn-OFF switch 450. Overshoot control logic block 440 can be implemented in a known way.

Magnitudes of the pre-determined durations (undershoot-on-time, overshoot-on-time), offset-1, offset-2, US-threshold and OS-threshold are programmable (e.g., configurable based on user input), and may be configured in THMA-1 (250) or be received as an input from an external device (not shown) or as a user input (via corresponding means not shown). Magnitudes of US-threshold and OS-threshold are based on RC values of resistor 404 and capacitance 403 of differentiator 405, designed for load-steps exceeding the desired magnitude.

In the illustrative embodiment (with Va-ref of 1 V, and designed to supply current to/sink current from node 240 only for to turn for load transients caused by load-steps exceeding 350 A), each of offset-1 and offset-2 equals 400 mV, although alternative embodiments may have unequal values for offset-1 and offset-2.

The description is continued to illustrate waveforms at various nodes of VRM 110 in transient conditions, in an embodiment of the present disclosure.

### 6. Operation of Transient Handling Module

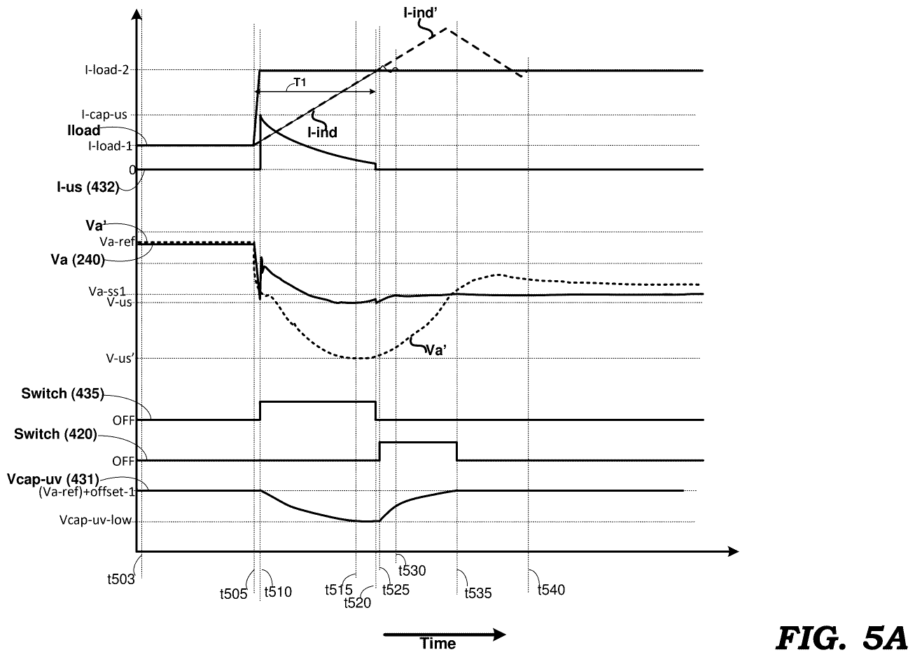

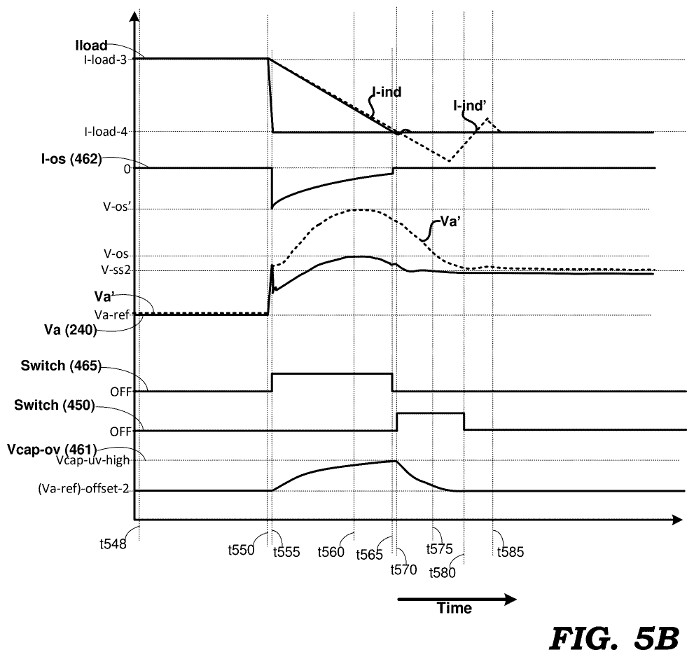

FIGS. 5A and 5B are timing diagrams (not to scale) illustrating the response of transient handling module 250 in an embodiment of the present disclosure. FIG. 5A shows example waveforms of Iload, I-us (432), Va (240), I-ind, Vcap-uv (431), and state of switches 420 and 435. FIG. 5B shows example waveforms of Iload, I-os (462), Va (240), I-ind, Vcap-ov (461), and state of switches 450 and 465. Iload represents load-current, and I-ind represents average inductor-current of Rail-A with the invention (i.e., THM-A is implemented as part of VRM 110). Waveforms I-ind′ and Va′ respectively depict the total inductor-current, and voltage at node 240 without the invention.

It is noted herein that the waveforms depicted in FIGS. 5A and 5B are for illustrative purposes only, and the specific shape of various waveforms (e.g., I-us/Va/Vcap-uv/I-os/Vcap-ov) would depend on several factors such as the inductance value of inductors 225, 425, 455, the capacitance value of capacitors 226A, 430, 460, bandwidth of feedback loop within phase controller 210, number of active power stages 220, and effect of transient handling module 250.

### I. Undershoot Condition

Rail-A of VRM 110 is in steady-state until time t505. Thus, Va is substantially equal to Va-ref, and switches 420 and 435 are in OFF condition. It is assumed that capacitor 430 has been pre-charged to voltage of magnitude (Va-ref plus offset-1) prior to t503.

At t505, Iload has a step increase from its current value Iload-1 to value Iload-2. The total inductor current supplied by VRM 110 however rises to Iload-2 only by time instant 520, limited by the bandwidth of the voltage regulation control loop of VRM 110. As a result, Va begins to fall below Va-ref (undershoot), starting at time instant t505. It is assumed that the load-step (Iload-2-Iload-1) is large enough to cause Vdiff to exceed US-threshold (408).

At t510, Vdiff is determined to have exceeded US-threshold and block 410 turns ON switch 435. Capacitor 430, pre-charged to (Va-ref plus offset-1) discharges to supply current I-us on path 432. Va reaches valley point V-us at time t515. It may be appreciated that upon occurrence of an undershoot, due to the quick brief transfer of charge from capacitor 430 to node 240, undershoot is minimized. Without the invention, the valley point of voltage at node 240 would have reached magnitude V-us' (as depicted by waveform Va′).

The magnitude of ‘offset-1’ can be determined in the following manner:

The area of the triangle enclosed by I-load and I-ind waveforms in interval T1 represents the total charge deficit (Q-undershoot) into Va 240 due to the load-step noted above. This charge deficit needs to be supplied by capacitor 430.

Area of the triangle enclosed by I-load and I-ind:

$$Q - undershoot = 1 / 2 * ( T 1 ) * ( I - step ) \qquad Equation ( 1 )$$

Referring to FIG. 5A, Q-undershoot equals: ½ *(t520 minus t505)*(I-load-2 minus I-load-1)

It may be appreciated that for a particular load-step, T1 depends on the loop bandwidth, inductance value of inductors 225A, magnitude of Vin, Va-ref, the number of phases, etc. and may be calculated a priori, or estimated from simulations, in a known way.

$$Q - undershoot also equals \text{:} C 1 * offset - 1 \qquad Equation ( 2 )$$

One of C1 and offset-1 can be set, and the other be calculated from Equation 2.

The area under waveform I-us (432) in interval T1 approximately equals Q-undershoot.

Time duration t510-t520 corresponds to the magnitude of ‘undershoot-on-time’ configured in THM-A. Thus, in duration t510-t520, capacitor 430 discharges and voltage across capacitor Vcap-uv is shown to be falling. At t520, block 410 turns OFF switch 435. Voltage across capacitor 430 reaches magnitude Vcap-uv-low. Subsequently, at t525, block 410 turns ON switch 420. Thus, capacitor 430 starts charging at t525.

Att535, voltage across Vcap-uv reaches magnitude (Va-ref plus offset-1). Accordingly, at t535 block 410 turns OFF switch 420.

It may be appreciated that without the invention, since the valley point of voltage at node 240 would have been of a magnitude V-us' (greater in magnitude than V-us), transient response by the feedback loop inside phase controller 210 would have taken a longer duration (e.g., till t540) to cause Va to reach steady-state value. With the invention, output voltage Va reaches steady-state magnitude of Va-ss1 by t530. Magnitude Va-ss1 is assumed to be within the tolerance range specification of Va-ref.

### II. Overshoot Condition

Rail-A of VRM 110 is in steady-state until time t550. Thus, Va is substantially equal to Va-ref, and switches 450 and 465 are in OFF condition. It is assumed that voltage across capacitor 460 is of magnitude (Va-ref-offset-2) prior to t548.

At t550, Iload has a step decrease from its current value Iload-3 to value Iload-4. The total inductor current supplied by VRM 110 however falls to Iload-4 only by time instant 565, limited by the bandwidth of the voltage regulation control loop of VRM 110. As a result, Va begins to rise above Va-ref (overshoot). It is assumed that the load-step is large enough to cause magnitude of Vdiff to exceed OS-threshold (438).

At t555, magnitude of Vdiff exceeds OS-threshold and block 440 turns ON switch 465. Capacitor 460 discharged to (Va-ref minus offset-2), charges to sink/draw current I-os on path 462. Va reaches peak point V-os at time t560. It may be appreciated that upon occurrence of an overshoot, due to the quick brief sinking of charge by capacitor 460 from node 240, overshoot is minimized. Without the invention, the peak point of voltage at node 240 would have reached magnitude V-os' (as depicted by waveform Va′). The magnitude of ‘offset-2’ can be determined in a manner similar to that described above with respect to FIG. 5A, based on the charge surplus to be sunk by capacitor 460 upon occurrence of an overshoot.

Time duration t555-t565 corresponds to the magnitude of ‘overshoot-on-time’ configured in THM-A. Thus, in duration t555-t565, capacitor 460 charges and voltage across capacitor Vcap-ov is shown to be rising. At t565, block 440 turns OFF switch 465. Voltage across capacitor 460 reaches magnitude Vcap-uv-high. Subsequently, at t570, block 440 turns ON switch 450. Thus, capacitor 460 starts discharging at t565.

At t580, voltage across Vcap-ov reaches magnitude (Va-ref-offset-2). Accordingly, at t580 block 440 turns OFF switch 450.

It may be appreciated that without the invention, the peak point of voltage at node 240 would have reached a magnitude V-os' (greater than magnitude of V-os), and transient response by the feedback loop inside phase controller 210 would have taken a longer duration (e.g., till t585) to cause Va to reach steady-state value. With the invention, output voltage Va reaches steady-state magnitude of Va-ss2 by t575. Magnitude Va-ss2 is assumed to be within the tolerance range specification of Va-ref.

Although the description herein is provided in the context of a multi-phase switching converter, several aspects of the present disclosure can be equally well applied in other types of switching converters such as stand-alone switching converters and TLVR, and would be obvious to one skilled in the relevant arts upon reading the disclosure herein.

In an embodiment, the techniques are implemented in a switching converter in low-voltage high-current applications in which the slew-rate of load-currents is usually very high (~5000 Amperes (A) per micro-second (us)), and there are stringent transient response time specifications that need to be adhered to when designing VRM 110. An example of such application is an AI (artificial intelligence) processor.

Thus, aspects of the present disclosure enable a switching converter to regulate output voltage while exhibiting an improved transient response.

### 7. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of FIGS. 1, 2, 3 and 4, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

In the instant application, the power and ground terminals are referred to as constant reference potentials.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

What is claimed is:

1. A switching converter comprising:
a high-side switch and a low-side switch coupled in series at a switching node, and together operable to provide a regulated output voltage at an output node based on an input voltage received at an input node; and
a transient handling module comprising a first circuit portion designed to handle an undershoot of said regulated output voltage, said first circuit portion comprising:
a first capacitor having a first terminal and a second terminal, said first terminal of said first capacitor being coupled to a constant reference potential;
a first switch coupled between said input node and said second terminal of said first capacitor; and
a second switch coupled between second terminal of said first capacitor and said output node,
wherein in a first time duration, said first switch is closed with said second switch being open such that said first capacitor is charged to a first voltage via said first switch,
wherein upon occurrence of said undershoot of said regulated output voltage following said first time duration, said second switch is closed for a second time duration with said first switch being open in said second time duration such that said output node is coupled to said first capacitor via said second switch to cause said first capacitor to supply current to said output node.

2. The switching converter of claim 1, wherein said transient handling module further comprises:
a second circuit portion designed to handle an overshoot of said regulated output voltage, said second circuit portion comprising:
a second capacitor having a first terminal and a second terminal, said first terminal of said second capacitor being coupled to said constant reference potential;
a third switch coupled between said constant reference potential and said second terminal of said second capacitor; and
a fourth switch coupled between said second terminal of said second capacitor and said output node,
wherein in a third time duration, said third switch is closed with said fourth switch being open such that said second capacitor is discharged to a second voltage via said third switch,
wherein upon occurrence of said overshoot of said regulated output voltage following said third time duration, said fourth switch is closed for a fourth time duration with said third switch being open in said fourth time duration such that said output node is coupled to said second capacitor via said fourth switch to cause said second capacitor to draw current from said output node.

3. The switching converter of claim 1, wherein said first voltage is higher than said regulated output voltage by a first offset value, wherein said second voltage is lower than said regulated output voltage by a second offset value.

4. The switching converter of claim 1, wherein said transient handling module comprises a differentiator coupled to receive said regulated output voltage, said differentiator designed to generate a first output signal with a magnitude proportional to a rate of change of said regulated output voltage,
wherein said undershoot of said regulated output voltage is determined to have occurred if said rate of change is positive and exceeds a first threshold,
wherein said overshoot of said regulated output voltage is determined to have occurred if said rate of change is negative and a magnitude of said rate of change exceeds a second threshold,
wherein said first offset value is based on said first threshold,
wherein said second offset value is based on said second threshold.

5. The switching converter of claim 4, wherein said first circuit portion further comprises a first control logic block operable to receive said regulated output voltage, said first output signal, and to generate a first gate-drive signal and a first control signal, said first gate-drive signal operable to control the opening and closing of said first switch, said first control signal operable to control the opening and closing of said second switch,
wherein said first control logic block is operable to close said second switch for said second time duration upon determining occurrence of said undershoot,
wherein said first control logic block is operable to close said first switch subsequent to opening said second switch.

6. The switching converter of claim 4, wherein said second circuit portion further comprises a second control logic block operable to receive said regulated output voltage, said first output signal, and to generate a second gate-drive signal and a second control signal, said second gate-drive signal operable to control the opening and closing of said third switch, said second control signal operable to control the opening and closing of said fourth switch,
wherein said second control logic block is operable to close said fourth switch for said fourth time duration upon determining occurrence of said overshoot,
wherein said second control logic block is operable to close said third switch subsequent to opening said fourth switch.

7. The switching converter of claim 4, wherein said first offset value and said second offset value are programmable.

8. The switching converter of claim 4, wherein said second time duration, said fourth time duration, said first threshold and said second threshold are programmable.

9. The switching converter of claim 6, wherein said first circuit portion further comprises:
a first inductor having a first terminal and a second terminal; and
a first diode having a cathode and an anode,
wherein said first switch is an n-type (Metal Oxide Semiconductor Field Effect Transistor) MOSFET, wherein said first switch comprises a first current terminal, a second current terminal and a control terminal, wherein said first current terminal of said first switch is coupled to said input node, wherein said second current terminal of said first switch is coupled to a junction of said cathode of said first diode and said first terminal of said first inductor,
wherein said anode of said first diode is coupled to said constant reference potential,
wherein said second terminal of said first inductor is coupled to said second terminal of said first capacitor,
wherein said control terminal of said first switch receives said first gate-drive signal.

10. The switching converter of claim 6, wherein said second circuit portion further comprises:
a third inductor having a first terminal and a second terminal; and
a second diode having a cathode and an anode,
wherein said third switch is an n-type MOSFET, wherein said third switch comprises a first current terminal, a second current terminal and a control terminal, wherein said first current terminal of said third switch is coupled to said constant reference potential, wherein said second current terminal of said third switch is coupled to a junction of said anode of said second diode and said first terminal of said second inductor,
wherein said cathode of said second diode is coupled to said input node,
wherein said second terminal of said second inductor is coupled to said second terminal of said second capacitor,
wherein said control terminal of said third switch receives said second gate-drive signal.

11. A voltage regulator module (VRM) comprising:
a power stage comprising a high-side switch and a low-side switch coupled in series at a switching node, and together operable to provide a regulated supply voltage of a desired magnitude at an output node based on an input voltage received at an input node; and
a transient handling module comprising a first circuit portion designed to handle an overshoot of said regulated output voltage, said first circuit portion comprising:
a first capacitor having a first terminal and a second terminal, said first terminal being coupled to a constant reference potential;
a first switch coupled between said constant reference potential and said second terminal of said first capacitor; and
a second switch coupled between said second terminal of said first capacitor and said output node,
wherein in a first time duration, said first switch is closed with said second switch being open such that said first capacitor is discharged to a first voltage via said first switch,
wherein upon occurrence of said overshoot of said regulated output voltage following said first time duration, said second switch is closed for a second time duration with said first switch being open in said second time duration such that said output node is coupled to said first capacitor via said second switch to cause said first capacitor to draw current from said output node.

12. The VRM of claim 11, wherein said transient handling module further comprises:
a second circuit portion designed to handle an undershoot of said regulated output voltage, said second circuit portion comprising:
a second capacitor having a first terminal and a second terminal, said first terminal of said second capacitor being coupled to said constant reference potential;
a third switch coupled between said input node and said second terminal of said second capacitor; and
a fourth switch coupled between said second terminal of said second capacitor and said output node,
wherein in a third time duration, said third switch is closed with said fourth switch being open such that said second capacitor is charged to a second voltage via said third switch,
wherein upon occurrence of said undershoot of said regulated output voltage following said third time duration, said fourth switch is closed for a fourth time duration with said third switch being open in said fourth time duration such that said output node is coupled to said second capacitor via said fourth switch to cause said second capacitor to supply current to said output node.

13. The VRM of claim 11, wherein said first voltage is lower than said desired magnitude of said regulated output voltage by a first offset value, wherein second voltage is higher than said desired magnitude of said regulated output voltage by a second offset value.

14. The VRM of claim 11, wherein said transient handling module comprises a differentiator coupled to receive said regulated output voltage, said differentiator designed to generate a first output signal with a magnitude proportional to a rate of change of said regulated output voltage,
wherein said overshoot of said regulated output voltage is determined to have occurred if said rate of change is negative and a magnitude of said rate of change exceeds a first threshold,
wherein said undershoot of said regulated output voltage is determined to have occurred if said rate of change is positive and exceeds a second threshold,
wherein said first offset value is based on said first threshold,
wherein said second offset value is based on said second threshold.

15. The VRM of claim 14, wherein said first circuit portion further comprises a first control logic block operable to receive said regulated output voltage, said first output signal, and to generate a first gate-drive signal and a first control signal, said first gate-drive signal operable to control the opening and closing of said first switch, said first control signal operable to control the opening and closing of said second switch,
wherein said first control logic block is operable to close said second switch for said second time duration upon determining occurrence of said overshoot,
wherein said first control logic block is operable to close said first switch subsequent to opening said second switch.

16. The VRM of claim 14, wherein said second circuit portion further comprises a second control logic block operable to receive said regulated output voltage, said first output signal, and to generate a second gate-drive signal and a second control signal, said second gate-drive signal operable to control the opening and closing of said third switch, said second control signal operable to control the opening and closing of said fourth switch,
wherein said second control logic block is operable to close said fourth switch for said fourth time duration upon determining occurrence of said undershoot,
wherein said second control logic block is operable to close said third switch subsequent to opening said fourth switch.

17. The VRM of claim 14, wherein said first offset value and said second offset value are programmable.

18. The VRM of claim 14, wherein said second time duration, said fourth time duration, said first threshold and said second threshold are programmable.

19. The VRM of claim 16, wherein said first circuit portion further comprises:
a first inductor having a first terminal and a second terminal; and
a first diode having a cathode and an anode,
wherein said first switch is an n-type (Metal Oxide Semiconductor Field Effect Transistor) MOSFET, wherein said first switch comprises a first current terminal, a second current terminal and a control terminal, wherein said first current terminal of said first switch is coupled to said constant reference potential, wherein said second current terminal of said first switch is coupled to a junction of said anode of said first diode and said first terminal of said first inductor,
wherein said cathode of said first diode is coupled to said input node,
wherein said second terminal of said first inductor is coupled to said second terminal of said first capacitor,
wherein said control terminal of said first switch receives said first gate-drive signal.

20. The VRM of claim 16, wherein said second circuit portion further comprises:
a third inductor having a first terminal and a second terminal; and
a second diode having a cathode and an anode,
wherein said third switch is an n-type MOSFET, wherein said third switch comprises a first current terminal, a second current terminal and a control terminal, wherein said first current terminal of said first switch is coupled to said input node, wherein said second current terminal of said first switch is coupled to a junction of said cathode of said first diode and said first terminal of said third inductor,
wherein said anode of said second diode is coupled to said constant reference potential,
wherein said second terminal of said second inductor is coupled to said second terminal of said second capacitor,
wherein said control terminal of said third switch receives said second gate-drive signal.
